(19) United States
(12) Patent Application Publication
(10) Pub. No.: US 2025/0126945 A1
(43) Pub. Date: Apr. 17, 2025

(54) Transfer Process for Micro Elements

(71) Applicant: Morphotonics Holding B.V., Veldhoven (NL)

(72) Inventors: Jan Matthijs Ter Meulen, Veldhoven (NL); Bram Johannes Titulaer, Veldhoven (NL); Rob Antonius Waltherus Neelen, Veldhoven (NL)

(21) Appl. No.: 18/729,275

(22) PCT Filed: Jan. 17, 2023
(86) PCT No.: PCT/NL2023/050017

§ 371 Date: Jul. 16, 2024

(30) Foreign Application Priority Data
Jan. 17, 2022 (EP) 22151742.8

(51) Int. Cl. H10H 29/03; H10H 29/02; H10H 29/80

(52) U.S. Cl. CPC H10H 29/03; H10H 29/02; H10H 29/942

(57) ABSTRACT

The invention relates a transfer process for micro elements, including at least one picking step wherein at least one micro element is picked up from at least one donor surface by at least one transfer surface and at least one placing step wherein at least one micro element is placed upon at least one receiving surface from at least one transfer surface, wherein the process according to the invention enables that at least the picking step benefits of several flexible parameters.

### CROSS-REFERENCE TO RELATED APPLICATIONS

This application is the United States national phase of International Patent Application No. PCT/NL2023/050017 filed Jan. 17, 2023, and claims priority to European Patent Application No. 22151742.8 filed Jan. 17, 2022, the disclosures of which are hereby incorporated by reference in their entireties.

### BACKGROUND OF THE INVENTION

### Field of the Invention

The invention relates to a transfer process for micro elements. The invention also relates to a system for transferring micro elements.

### Description of Related Art

Transfer processes for micro elements such as micro light emitting diodes (micro-LEDs) are known in the art. Micro-LEDs can be used in various application and play for example an important role in the functionality of displays. For color displays, every pixel is represented by three micro-LEDs, wherein each of such triple of micro-LEDs typically comprises one red, one green and one blue micro-LED which are steered separately. A high-definition display of 4K standard typically comprises around 24 million micro-LEDs which have to be placed on the display surface very accurately in order to secure that every micro-LED is steered properly.

Micro-LEDs are typically light-emitting diodes from inorganic materials which have a size of 100×100 μm or less. Micro-LEDs are typically produced on wafers of silicon, sapphire glass, gallium arsenide or glass. Wafers of defined crystal structures and with surfaces being cuts through defined lattice planes are necessary as templates for the epitaxial growth of the different layers forming micro-LEDs. On one wafer, typically only micro-LEDs of one color (e.g. red, green or blue) can be produced. In general, production of micro-LEDs is a very time-consuming process wherein the different layers are grown typically by physical and/or chemical vapor deposition techniques. As micro-LEDs have to be produced batchwise and the size of suitable wafers is currently limited to a diameter of 300 mm, the number of micro-LEDs that can be produced per batch is limited and due to the time-consuming process, micro-LEDs are considerably expensive components. Efficient procedures for handling thereof are thus indispensable.

In order to achieve a multi-colored display or areas emitting white light using micro-LEDs, micro-LEDs have to be transferred from the wafers, on which they are produced, to the display substrate. The wafers act thus as a donor wafers. Transferring has to be carried out in such a way that the micro-LEDs are transferred from donor wafers typically carrying only red, green or blue micro-LEDs, respectively, to a display substrate or transfer substrate where red, green and micro-LEDs are properly distributed and placed in triples which together may form a white pixel of a display or a white dot of a white light emitting area.

As per display millions of micro-LEDs might have to be placed properly in order to avoid pixel errors which are not accepted by the customer, placing of micro-LEDs is a great challenge due and a time-consuming process to the required accuracy and due to the fact that micro-LEDs as such are rather expensive. This challenge increases with the size of the displays to be produced as the donor wafers are at the moment of filing limited in size to a diameter of 12 inches (about 30 centimeters) which necessitates that micro-LEDs from multiple donor wafers have to be properly transferred to a display substrate which may have dimensions of half a meter or more.

In document U.S. Pat. No. 9,583,450 for example a non-contacted method for transferring light-emitting elements onto a package substrate is disclosed. In this method the supporting substrate is a blue tape, a light release tape, a thermal release tape or a substrate with magnetic characteristics. This makes the method complex, because the light-emitting elements can only be delivered on certain substrates.

Document U.S. Pat. No. 10,020,293 discloses a method for transferring micro-LEDs whereby the micro-LEDs are provided onto a laser-transparent substrate. By irradiation of the substrate with laser light the micro-LEDs are lift-off from the substrate. Also here, a special kind of substrate for delivering the micro-LEDs is necessary.

In document WO 2017/107097 a micro-LED transfer method is disclosed, in which a plurality of bonding layers is used to transfer the micro-LEDs onto a carrier substrate. The method is complex due to the use of a plurality of layers for transferring the micro-LEDs.

In the processes of the prior art, micro elements are typically transferred to web-like transfer surfaces which may have a length of several tens or several hundreds of meters but of very limited wideness. This necessitates that e.g. large displays have to be assembled from a large amount of narrow strips on which micro-LED have been placed properly. However, the larger the amount of segments from which a display is assembled, the higher is the probability of production errors. Thus, precision of the transfer processes is of utmost importance. However, especially complex processes as discussed in the prior art suffer from precision deficiencies due to their complexity and are time consuming.

### SUMMARY OF THE INVENTION

It is an aim of the present invention to overcome or to reduce at least part of the disadvantages of the prior art. A particular aim is to simplify and speed up the transfer of micro elements.

The invention provides thereto a transfer process for micro elements, comprising
at least one picking step wherein at least one micro element is picked up from at least one donor surface by at least one transfer surface; and
at least one placing step wherein at least one micro element is placed upon at least one receiving surface from at least one transfer surface;
   wherein prior to a placing step at least two picking steps, and preferably multiple picking steps, are performed and wherein the mutual orientation and/or mutual position of at least one donor surface and at least one transfer surface is altered before each subsequent picking step.

The transfer process according to the present invention is in particular configured such that at least one transfer surface gets into contact with a different part of at least one donor surface at each subsequent picking step. A major advantage of the transfer process according to the present invention is that at least two, and preferably multiple picking steps are performed prior to a placing step. This will significantly speed up the transfer process. It is possible to perform multiple picking steps subsequently due to the altering of the mutual orientation and/or orientation of at least one donor surface and at least one transfer surface. The transfer process according to the invention in particular benefits of the ability to efficiently pick multiple micro elements from at least one donor surface in an efficient manner. For example, the process enables that adjacent micro elements can be picked in subsequent steps whilst being placed upon the receiving surface simultaneously. Another advantage of the transfer process according to the present invention is that the process provides for a high accuracy due to the ability to alter the mutual orientation of at least one donor surface and at least one transfer surface. Yet a further benefit is that the transfer surface can be reused multiple times for different transfer processes. Due to the efficiency of the process, the transfer surface is barely prone to wear and tear. It was experimentally found that the transfer surface only experiences a minimal degree of wear resulting in a relatively long lifespan of the transfer surface. Therefore, replacement of the transfer surface can be minimized which is beneficial from economical point of view but also saves times since installing and initial outlining of the transfer surface is time consuming. The ability to continuously reuse the transfer surface for multiple transfer process also increases the accuracy and repeatability of the transfer processes.

When it is referred to a receiving surface, also a target surface can be meant. The transfer surface can for example form part of a (flexible) stamp. In the context of the present invention, a donor surface is defined as a surface comprising typically multiple micro elements, which micro elements can be picked off or donated from said surface. At least one donor surface may be comprised by at least one wafer. At least one donor surface can for example form part of a wafer, for example a wafer comprising multiple micro elements such as micro-LEDs.

The present invention also relates to a process or method for transferring micro elements, comprising the steps of:
providing at least one donor surface comprising a plurality of micro elements;
providing at least one receiving surface configured for receiving a plurality of micro elements; and
providing at least one transfer surface, wherein at least
   one transfer surface is configured for picking at least one micro element, and in particular a plurality of micro elements from at least one donor surface and wherein at least one transfer surface is configured for placing at least one micro element, and in particular a plurality of micro elements upon at least one receiving surface,
picking at least one micro element and in particular a plurality of micro elements from at least one donor surface by at least one transfer surface;
altering the mutual orientation and/or position of at least one donor surface and at least one transfer surface;
picking at least one micro element and in particular a plurality of micro elements from at least one donor surface by at least one transfer surface; and
placing at least part of the picked micro element upon at least one receiving surface.

Preferably, at least one transfer surface is substantially flexible. The use of a transfer surface which is at least substantially flexible can positively contribute to an improved transfer of micro elements. It is for example conceivable that at least one transfer surface forms part of a flexible stamp. At least part of at least one transfer surface can for example be used in combination with at least one roller or rotational element. It is for example conceivable that at least one picking step is performed by a rotational and/or rolling movement of at least one transfer surface with respect to at least one donor surface and/or that at least one placing step is performed by a rotational movement of at least one transfer surface with respect to at least one receiving surface. The use of a substantially flexible transfer surface can facilitate that a rotational movement can be performed without negatively affecting the transfer surface. The use of a rotational movement of at least one transfer surface with respect to at least one donor surface is efficient and effective from a spatial point of view. The rotational and/or rolling movement can be configured such that a rotational and/or rolling movement of at least 25 degrees is performed, preferably at least 45 degrees, more preferably at least 90 degrees. It is also conceivable that a rotational and/or rolling movement of at least 100 degrees is performed, preferably at least 135degrees, more preferably at least 180 degrees. However, it is also conceivable that the mutual displacement between the transfer surface and the donor surface(s) required for the picking step is a linear oriented displacement, for example in the z-direction.

It is also conceivable that at least one transfer surface has a Youngs modulus of less than 10 GPa, preferably less than 4 GPa, preferably less than 3 GPa, more preferably less than 2 GPa. It is also conceivable that at least one transfer surface has a Youngs modulus of less than 80 GPa, preferably less than 40 GPa, preferably less than 10 GPa, more preferably less than 2 GPa. It is also conceivable that the Youngs modulus is in range of 0.1 to 200 GPa, in particular in the range of 40 to 80 GPa The Youngs Modulus is for example measured according to ASTM E111. Such embodiment facilitates a sufficient flexibility whilst the textured area, if applied, is not affected. The flexibility of at least one functional element, if applied, may be the same or higher than the flexibility of the transfer surface.

In a possible embodiment at least one transfer surface comprises sheets of thermoplastic polymers, such as polyethylene terephthalate which may be reinforced e.g. by thin glass sheets embedded thereto. The flexible transfer surface may be a flexible stamp, a flexible roller or any combination thereof. The transfer surface may be a sheet of flexible material such as a plastic foil or a laminate comprising at least one plastic foil. In such a laminate, apart from plastic foils, also reinforcing materials such as thin glass sheets, reinforcement fibers or reinforcing fabric may be comprised. Furthermore, the transfer surface may comprise at least one electric circuit and/or an electric functional element such as an electrical resist heater, a light emitting diode or an actuator such as a piezo unit or a motor. The flexible transfer unit comprises an active area. The active area is the area wherein micro elements can be picked up and released. The active area may comprise any special means to pick and to release micro elements such as a special relief, a special composition of the surface or any other suitable means known to the skilled person. In case the transfer surface is a sheet of flexible material, it may be used together with a roller. A roller according to the present application is a cylindrical device that is mounted in such a way that it is able to rotate and to exert pressure onto an item that is passing underneath the roller.

The transfer surface may be fixed to the roller, or it may not be fixed to the roller. In case the transfer surface is not fixed to the roller, the transfer surface may be guided between the roller and the donor surface(s) and between the roller and the receiving surface in such a manner that the roller can exert pressure to the transfer surface and through the transfer unit to the donor surface or the transfer surface in order to carry out the picking step and/or the placing step. In order to carry out the picking step and/or the placing step properly, the pressure that is exerted by the roller may be steered. The pressure is typically significantly influenced by the gap height between the transfer surface and the donor surface(s) and has to be chosen carefully in order to make sure that, first, the picking steps are carried out properly and reliably and that, second, the neither the micro elements nor the transfer surface and/or the donor surface are damaged. Control of the gap size between the transfer surface and the donor surface may be carried out by all means known in the art. Possible ways are e.g. a fixed position of the transfer surface in relation to the donor surface and, at the same time, the donor surface is provided in such a way that it cannot be moved in a moving plane which is parallel to the donor surface but that it cannot move out of said moving plane. In order to steer the picking steps or the placing step(s), the roller, if applied, may comprise means for temperature control. Depending on the mechanism which is used in the picking step and the placing step. The roller may be heated or cooled to allow e.g. for easy pick up or easy release of the micro elements by the transfer surface. The roller may thus comprise means for heating and/or cooling such as pipes and/or hoses which allow for heating and/or cooling by steam, water or other heating and/or cooling agents, an electrical resist heater or a Peltier device which allows for both heating and cooling. By heating and/or cooling of the roller, also the transfer surface, which is in contact with the roller, may be heated and/or cooled.

In order to keep the temperature constant, the roller may furthermore comprise a thermostatic unit that monitors the temperature and steers the means for heating and/or cooling.

It is for example conceivable that at least one picking step is a pressure initiated picking step and/or that at least one placing step is a pressure initiated placing step. It is conceivable that at least one picking step is done via physical contact between at least one micro element and at least one transfer surface and/or that at least one placing step is done via physical contact between at least one micro element and at least one receiving surface.

Typically, the mutual distance between the donor surface and the transfer surface is reduced during the picking step and/or the mutual distance between the transfer surface and the receiving surface is reduced during the placing step.

Typically, at least one donor surface extends in a plane that defines an x-direction and a y-direction. Said plane may also define a z-direction. In a possible embodiment of the transfer process according to the invention, the mutual orientation of at least one donor surface and at least one transfer surface is altered in the x-direction and/or the y direction before each subsequent picking step. This embodiment enables that at least one transfer surface gets into contact with a different part of the donor surface during each picking step. It is for example conceivable that at least one donor surface is altered in the x-direction and/or the y direction with respect to the transfer surface before each subsequent picking step. It is also possible that at least one transfer surface is altered in the x-direction and/or the y direction with respect to the donor surface before each subsequent picking step. A combination thereof is imaginable too. Due to the movable arrangement of the donor surface and/or the transfer surface there is a high flexibility to pick up micro elements at different positions on the donor surface. Additionally, subsequent placing of the micro elements can be done at different positions on the receiving surface. Thus, the transfer process can be used for a wide variety of transfer processes and applications. The transfer process further enables for a high precision rate.

It is beneficial if the mutual orientation of at least one donor surface and at least one transfer surface is altered by at least one predetermined distance before each subsequent picking step. This can for example be in the x-direction and/or the y-direction. It is for example possible that said predetermined distance is determined based upon at least one characteristic of at least one micro element. Such characteristic can for example be the length and/or width of at least one micro element. It is also conceivable that the predetermined distance is defined based upon the characteristics of at least one donor surface, such as for example upon the number of micro elements and/or the outlining of micro element upon the donor surface.

Preferably, at least one transfer surface comprises at least one textured area. The texture of the textured area is in particular a three-dimensional texture. The textured area may be a three dimensionally textured area comprising depressions and elevations. It is for example possible that at least part of the textured area comprises a repeated pattern. It is also conceivable that at least part of the textured area is a randomized texture. The texture of the textured area may comprise diffractive gratings, slanted gratings, blazed gratings, micro-lens arrays, lenticulars, pillars, bars, pyramids, prism lines and/or combination thereof. It can also be said that the transfer surface comprises at least one active area, in particular wherein said active area comprises the texture. The active area may differ from the rest of the transfer surface. The depth of the texture of the textured area can for example be in the nanometer to micrometer scale. It is for example conceivable that at least part of the texture has a dept in the range of 0.1 nm to 100 μm. It is also conceivable that at least part of the texture of the textured area comprises a peak to valley height of at most 1 mm. Preferably, at least part of the texture comprises a peak to valley height of at most 10 μm, more preferably at most 5 μm and even more preferably at most 2 μm. However, it is also conceivable that at least part of the texture of the textured area comprises a peak to valley height of at most 100 nm, more preferably at most 50 nm and even more preferably at most 20 or 10 nm.

In an embodiment, the textured area of the transfer surface comprises a pattern of elevations with each elevation having a surface area which is smaller than the surface area of a micro element which is to be transferred, for example at most 10% smaller. It is also conceivable that the textured area of the transfer surface comprises a pattern of elevations with each elevation having a surface area which is larger than the surface area of a micro element which is to be transferred. Possibly, the elevations are arranged in lines and columns and the distance of every elevation to the adjacent elevations in the same line and the distance of every elevation to the adjacent elevations in the same column does not differ by more than 1%. In an embodiment, the distance between two elevations in the same line is larger than two times the width of a micro element to be transferred. In an embodiment, the distance between two elevations in the same columns is larger than two times the height of the micro elements to be transferred.

Typically, within the context of the present invention, the surface of at least one textured area is smaller than the total surface of the transfer surface. The textured area can for example be centrally located upon or in the transfer surface. The side edge(s) of the transfer surface are preferably free of texture. It is conceivable that at least part the transfer surface is compressible. For example, at least part of the textured area may be compressible.

In a further possible embodiment, at least one transfer surface comprises at least one functional element. It is also possible that at least one functional element is a functional grid. At least one functional element can for example be aligned with at least part of the textured area. The functional element, if applied, can for example be applied to monitor, condition or control the process conditions when the same transfer surface is used during multiple runs. It is for example conceivable in practice that at least part of the transfer surface experiences temperature differences during continuous or repeated use. It is for example possible that part of the transfer surface heats up, which may affect the performance of the transfer surface. Therefore, at least one functional element can be used to compensate and/or counteract for the caused deviations. In a preferred embodiment, at least one functional element is a conductive element, in particular an electrically conductive element. It is also conceivable that at least one functional element is a thermally conductive element or a heating element. It is beneficial to comprise at least one conductive element, as in this way the conductive character of the functional element can compensate and/or counteract for any deviations caused during use of the transfer surface. In this way, a more repeatable result can be obtained, for example identical products or at least products with reduced product deviation. The use of at least one functional element, such as a conductive element may also result in a longer lifespan of the transfer surface, for example because the functional element can contribute to preservation of the textured area by maintaining optimal process conditions during use of the transfer surface. The transfer surface, and in particular the functional element, can for example also be configured such that predetermined pre-conditions which should be met to successfully perform the transfer process. Monitoring parameters that relate to the pre-conditions is an effective method to gather data, statistics and perform quality control. Non-limiting examples thereof are a functional element monitoring the starting temperature and/or local temperature of the transfer surface and/or a functional element monitoring the strain on the transfer surface during the transfer process. At least one functional element could further positively contribute to aligning at least one transfer surface with respect to at least one donor surface and/or at least one receiving surface.

At least part of at least one functional element can be made of at least one conductive material, in particular at least one electrically conductive material. Within this context, an electrically conductive material can for example be classified as a material that does not change its chemical composition while conducting electric energy and which shows an electrical resistivity of 100 (Ωmm^2)/m or less. It is beneficial if at least one conductive material comprises at least one metal, at least one non-metallic inorganic compound and/or at least one electrically conductive polymer. It is also conceivable that at least one conductive material comprises a combination of such materials. Non-limiting examples of metals which can be applied are iron, aluminium, copper, silver, gold, tin or any alloy thereof. It is also conceivable that at least one (electrically) conductive material comprises a non-metallic inorganic compound or element such as but not limited to graphite, graphene, carbon nanotubes, carbon fibers and/or niobium oxide. The electrically conductive material may furthermore be an electrically conductive polymer such as polyacetylene, poly-3,4-ethylendioxythiophen, polypyrrol or any other electrically conductive polymer known to the person skilled in the art. It is for example conceivable that at least one functional element comprises wires and/or ribbons. At least one functional element may comprise a mesh of conductive material and/or a wire mesh. It is also conceivable that at least one conductive material comprises at least one doped metal oxide. At least one doped metal oxide can for example be chosen from the group of: indium-tin oxide (ITO), antimony-doped tin oxide (ATO), aluminium-doped zinc oxide (AZO), indium doped zinc oxide (IZO) and/or gallium doped zinc oxide (GZO). Such materials benefit of a relatively good transparency and/or being substantially translucent. This is beneficial as the material then would not significantly affect radiation through the material which might be applied for the transfer process.

In an embodiment the transfer surface is a flexible sheet containing devices for electrically steered pick and place. Electrically steered pick and place can be carried out using three different approaches. These three different approaches will be discussed in the following in their order not to be understood to be any kind of ranking. All discussed approaches of electrically steered pick and place may furthermore be combined. The first approach is electrostatic steered pick and place where electrodes are present in the transfer surface which serve as capacitor plates and which, upon application of voltage, form an electric field. The electrical field may be switched on in order to pick up at least one micro element, may be kept to hold the micro element and may be switched off to release a micro element. The transfer surface may comprise a plurality of electrodes which electrodes allow for selective picking and placing of micro elements. Control of said plurality of electrodes may be carried out using an electronic circuit which may be comprised in the transfer surface.

The second approach is electromagnetic pick and place where the micro elements have to be magnetic or at least comprise a magnetic component. For magnetic pick and place the transfer surface may comprise at least one inductivity such as e.g. an electromagnetic coil which forms an electromagnetic field. Said electromagnetic field may be switched on to pick up a micro element, may be kept to hold the micro element and may be switched off to release a micro element. The transfer surface may comprise a plurality of inductivities which inductivities allow for selective picking and placing of micro elements. Control of said plurality of inductivities may be carried out using an electronic circuit which may be comprised in the transfer surface. The third approach is electromechanical pick and place where micro elements are picked by electromechanical actuators such as piezo elements which work like tweezers and wherein electrical pulses may induce pick up and release of micro elements. The transfer surface may comprise a plurality of electromechanical actuators for selective picking and placing of micro elements. Control of said plurality of electromechanical actuator may be carried out using an electronic circuit which may be comprised in the transfer surface. Picking and placing of micro elements may furthermore be carried out by adhesion either using van-der-Waals forces or adhesive agents. Picking and placing using van-der-Waals forces uses the differences in van-der-Waals forces between the material of the transfer surface, the micro element and the donor surface and/or receiving surface. In order to pick up the micro element, the van-der-Waals force between the transfer surface and the micro element must be larger than the van-der-Waals force between the micro element and the donor surface. Thus, the micro element is held by transfer surface through van-der-Waals forces. Release of the micro element may then be carried out also by van-der-Waals forces by choosing the surface of the receiving surface such that the van-der-Waals forces between the surface of the receiving surface and the micro element is larger than the van-der-Waals force between the micro element and the transfer surface. It is noted that different surfaces of the micro element do not necessarily have to have the same chemical properties and thus may be different in their characteristics concerning van-der-Waals forces.

Picking and placing using adhesive agents uses the different adhesion strengths of different adhesives. The transfer surface may in total or in part be provided with a first adhesive to which the micro elements adhere stronger to than to the donor surface. By using said first adhesive, the micro elements may come loose from the donor surface and stick to the transfer surface. The receiving surface may then be covered with a second adhesive to which the micro element adheres stronger than to the transfer surface. In this way, the micro elements can be moved from the transfer surface and be placed on the receiving surface.

It is understood that all approaches of picking and placing—be it electrical steered pick and place or pick and place by adhesion may be combined in any manner.

When the picking process is carried out using adhesion—be it using van-der-Waals forces, adhesive agents or any combination thereof, the transfer step may be electrically steered and vice versa. Thus, the receiving surface may be put on an electrical potential in order to form an electric field that is strong enough to release the micro elements from the transfer surface. Also, magnetic fields may be used to release the micro elements from the transfer surface.

It is understood that any picking and placing process described for the present invention may be combined with techniques to modify the binding force of the micro elements to the donor surface(s) and/or the receiving surface. This modification of the binding force may be carried out by any technique known to the person skilled in the art such as heating by a laser, removing of a binding layer by an etching process or use of adhesives of adhesion may be altered using heat, light or any other technique known to the skilled person.

It is preferred that at least one functional element, if applied, comprises at least one sensor. The use of at least one sensor can add further functionality and/or controllability to the transfer surface. It is for example conceivable that at least one sensor is a temperature sensor, a strain sensor, pressure sensor, position sensor, force sensor, piezo sensor, humidity sensor or an optic sensor. It is also possible that a plurality of sensors is applied, which can be the same or different sensors. It is further imaginable that at least one functional element is chosen from the group of: a heating element, a load cell array, a gripper array, a strain sensor, a recognition tag, RFID tag, a temperature sensor and/or a piezo element. Non-limiting examples of piezo elements which can be applied are a piezo actuator, a light-emitting diode, a capacitor and/or any combination thereof. It is for example possible that the transfer surface comprises multiple sensors, for example pressure and/or temperature sensors, which are distributed over the transfer surface, wherein each sensor is positioned outside the textured area, if applied. It is also possible that at least one functional element is a heating element such as a heating pad. Possibly, at least one functional element comprises at least one electric circuit. The transfer surface may further comprise, or cooperate with, at least one control unit which can adjust at least one functional element based upon data obtained during use of the transfer surface.

It is also conceivable that at least one functional element, if applied is provided via deposition, sputtering and/or printing. At least one functional element can be at least partially embedded in the transfer surface. Hence, it is possible that at least part of at least one functional element is embedded in the transfer surface and that a further part of the functional element is present at a(n) (outer) surface of the transfer surface. Typically, at least one transfer surface comprises a front surface and a rear surface. It is possible that at least part of at least one functional element is at the rear surface of the transfer surface and that the textured area is at the front surface of the transfer surface. In this way, the functional element can be at a distance from the textured area.

The transfer surface may also comprise multiple functional elements. It is conceivable that the transfer surface comprises at least two functional elements. The transfer surface may also comprise a plurality of functional elements. This can be the same (type of) functional elements. It is also conceivable that the transfer surface comprises multiple functional elements, wherein at least two different types of functional elements are present. Hence, it is for example conceivable that at least one functional element comprises a conductive element and that at least one functional element comprises a sensor. It is imaginable that at least one functional element fully covers and/or overlaps with at least one textured area and that at least one further functional element is positioned outside the textured area. In case multiple functional elements are applied, it is conceivable that at least two functional elements are actuated individually. It is also conceivable that at least two functional elements are placed in parallel and/or in series.

In an embodiment, at least one functional element can be pixilated. This means that that for example not one large functional electric device is comprised in the transfer surface but that the active area of the transfer surface or parts thereof are tiled by a plurality of small functional electrical components which selectively may be switched on and off and/or steered and may thus carry out their functions at specific locations. The pixilated electrical component may e.g. be pixilated heating pads, pixilated gripper arrays, pixilated piezo actuators, pixilated light sources or any combination thereof. Actuators such as piezo actuators may further be used as ultrasonic heaters for lowering the viscosity of resin underneath or in the vicinity of the transfer surface. The sensors may be pixilated and thus, the transfer surface may comprise pixilated pressure sensors such as load cell arrays, pixilated strain sensors, pixilated temperature sensors or pixilated light sensors or any combination thereof. Said pixilated sensors may allow for specific detection of said physical effects for regions under the transfer surface. A pixilated functional electrical component or a pixilated sensor according to the application is a functional electrical component or a sensor which is comprised in the transfer surface at least twice with the two devices having no spatial overlap and with the two devices being able to be used selectively for the region they are covering. Throughout this application, the term “pixilated” is not to be understood in such a way that the elements of a pixilated device have to form a closed area or are in direct vicinity to each other. Elements of a pixilated device may be distributed over an area with space between different elements which may be a multiple of the size of the elements. In an embodiment, the transfer surface may comprise a combination of pixilated sensors and pixilated functional electric components. In an embodiment at least two sensors might be placed symmetrically at both sides of the active area of the transfer surface for example along the imprint direction. In an embodiment at least two sensors might be placed in a row at one or both sides of the active area across the imprint direction also called as the start or stop side of the transfer surface. In an embodiment the sensors might be placed in a circle surrounding the active area or active areas.

At least part of at least one textured area of the transfer surface, if applied, is preferably imprinted upon the transfer surface. It is for example conceivable that at least one textured area is imprinted into a layer of resin on the transfer surface.

At least one picking step involves typically picking up a plurality of micro elements. It is for example also possible that at least one picking step involves picking up a plurality of micro element from a plurality of donor surfaces. In this way, further efficiency of the picking process can be achieved. In a further preferred embodiment, at least one picking step involves picking up a plurality of micro elements, wherein at least two micro elements originate from different donor surfaces. In a possible embodiment, more than 5, 10 or 15 donor surfaces can be simultaneously transferred during the transfer process. In an embodiment, during one transfer process more than one donor surface is used at the same time during the process. It is for example conceivable that different types of micro elements are picked up in a single picking step. The different types of micro elements may originate from the same donor surface or from different donor surfaces. This is for example possible if at least two donor surfaces are aligned such that the transfer surface can pick up micro elements from each donor surface during a picking step.

In a preferred embodiment, at least one micro element comprises a micro light emitting diode (micro-LED). Such micro-LEDs can for example be light-emitting diodes from inorganic materials which have a size of 100×100 μm or less. It is conceivable that different types of micro-LED are involved in the transfer process according to the present invention, for example red, green and/or blue micro-LEDs. The micro-LEDs could basically emit any color, for example red, infrared, ultraviolet, green, yellow and/or blue.

Preferably, the area defined by at least one receiving surface is larger than the area defined by at least one donor surface. The transfer process according to the present invention is preferably configured to facilitate efficient transfer of micro elements. The donor surface(s) are typically rather densely loaded with micro elements. Typically, each donor surface comprises a single type of micro element.

In a preferred embodiment the donor surface has a squared or rectangular form. The receiving surface is typically configured to receive a plurality of multiple types of micro element. The transfer process according to the present invention enables the transfer and spreading of micro element in an efficient manner. The area defined by the transfer surface may substantially equal the area defined by the receiving surface.

At least one receiving surface can for example be a display or a display substrate, for example an LCD, QLCD, OLED and/or plasma display. At least one receiving surface can be substantially flat. At least one receiving surface can also comprise a strip, a circuit board and/or the front panel of a display. The front panel of a display may be equipped with an electrical CMOS or TFT array, especially in case the micro elements are micro elements which may be driven using CMOS or TFT arrays.

The transfer process according to the invention may further comprise the step of adjusting the mutual orientation of at least one receiving surface and at least one transfer surface prior to a placing step. In this way, outlining of the receiving surface and the transfer surface can be done.

The invention also relates to a transfer surface for use in a transfer process according to the present invention.

The invention further relates to a system for transferring micro elements, in particular via a transfer process according to the present invention, the system comprising:
at least one carrier configured for carrying at least one donor surface and/or at least one receiving surface; and
at least one transfer surface;
   wherein the mutual orientation of at least part of the carrier and at least one transfer surface can be altered in at least two directions.

The system is in particular configured to perform the transfer process according to the present invention. Any embodiment as described for the transfer process can apply to the system too. At least one carrier is preferably configured for carrying multiple donor surfaces. At least one carrier could for example comprises at least one displaceable retaining structure, or tray, which is configured for carrying and/or retaining at least one donor surface and/or at least one receiving surface, and wherein at least one retaining structure is displaceable with respect to the carrier in at least two directions. The retaining structure could also be referred to as stage or tray. At least one retaining structure extends typically in a plane that defines an x-direction and a y-direction. At least one retaining structure can be configured to be altered in the x-direction and/or the y direction, for example with respect to the carrier and/or the transfer surface. In this way, outlining of the donor surface(s) carried by the retaining structure can be outlined with respect to the transfer surface in an efficient manner. At least carrier and at least one transfer surface are preferably mutually displaceable via a rotational movement. The system may for example comprise at least one roller or rotational element to facilitate rotational and/or rolling movement, in particular of the transfer surface. It is possible that the carrier and the transfer surface are displaceable in the z-direction and further in the x-direction or the y direction. It is for example conceivable that at least one transfer surface is (directly or indirectly) connected to the carrier such that the carrier can be displaced with respect to the transfer surface in a longitudinal direction, for example an x-direction or y-direction, thereby initiating rotation movement of the transfer surface over a roller. It is conceivable that the degree of adhesion of the transfer surface adjustable and/or that a pressure applied by the transfer surface is adjustable. The system may also comprise at least one housing wherein at least one carrier and/or at least one transfer surface is received within said housing. It is for example conceivable that the carrier is displaceable received within the housing. The transfer surface can be fixated to a (stationary) part of the housing and to the carrier, such that displacement of the carrier initiates the transfer surface to displace too, in particular in a rotational manner over a roller. The system may further comprise at least one control unit, which is at least configured to control the mutual orientation of at least part of the carrier and at least one transfer surface.

### BRIEF DESCRIPTION OF THE DRAWINGS

The terms Fig., Figs., Figure, and Figures are used interchangeably in the specification to refer to the corresponding figures in the drawings.

The invention will be further elucidated by means of non-limiting exemplary embodiments illustrated in the following figures, in which:

FIGS. 1a-1f shows the steps of a transfer process according to the present invention by making use of a system according to the present invention;

FIGS. 2a and 2b show a schematic representations of an example of a picking step according to the present invention;

FIGS. 3a-3g show a further schematic representation of a possible transfer process according to the present invention;

FIGS. 4a-4d show a further possible embodiment of a picking step according to the present invention; and

FIGS. 5a and 5b show an example of a further possible donor surface which can be used in a transfer process according to the present invention.

Within these figures, similar reference numbers correspond to similar or equivalent elements or features.

### DESCRIPTION OF THE INVENTION

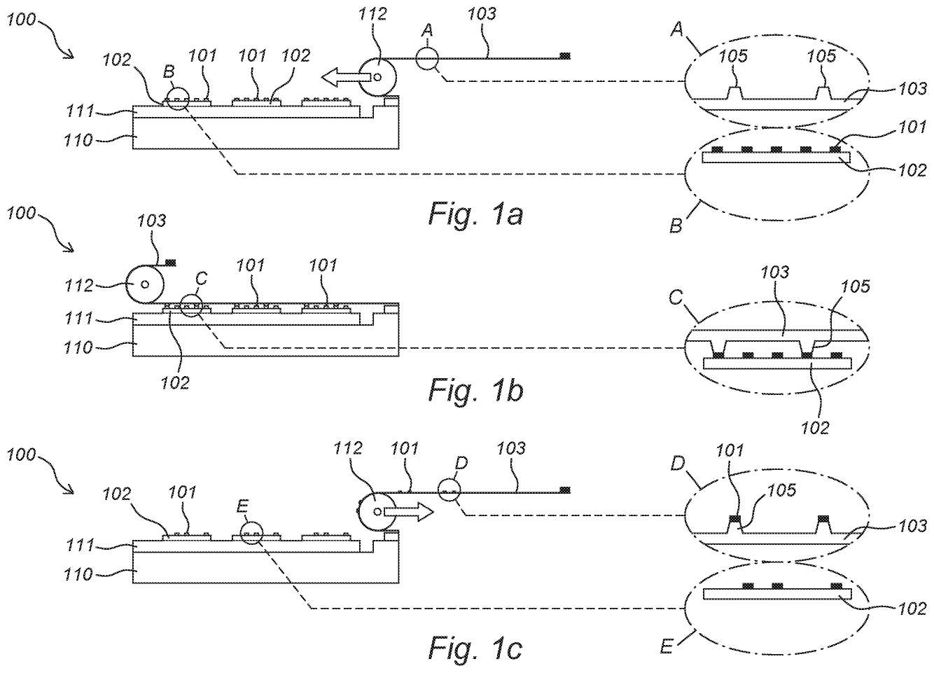

FIGS. 1a-1f show a schematic representation, in side view, of the steps of a transfer process according to the present invention by making use of a system 100 according to the present invention. The system 100 is configured for transferring micro elements 101. The system 100 comprises a carrier 110 configured for carrying donor surfaces 102 and/or at least one receiving surface 104. The system 100 also comprises a transfer surface 103. The mutual orientation of at least part of the carrier 110 and the transfer surface 103 can be altered in at least two directions. In the shown embodiment, the transfer surface 103 is substantially flexible and the picking steps are performed by a rotational movement of the transfer surface 103 with respect to the donor surface(s). The flexible transfer surface 103 is rotatable around a roller 112.

FIG. 1a shows an initial situation wherein the transfer surface 103 and the donor surfaces 102 are positioned at a distance from each other. Detailed views of the transfer 103 and the donor surface 102 comprising micro elements 101 are shown too. The transfer surface comprises a textured area comprising multiple elevations 105.

In FIG. 1b, the mutual orientation of the transfer surface 103 and the donor surfaces 102 is altered, such that at least one picking step can be performed wherein micro elements 101 are picked up from the donor surface(s) 102 by the transfer surface 103. In the detailed view, it can be seen that the elevations 105 of the textured area of the transfer surface 103 are in contact with the micro elements 101.

FIG. 1c shows that a plurality of micro elements 101 has been transferred from the donor surface(s) 102 to the transfer surface 103. There are still micro elements 101 left on the donor surface(s) which can be picked up by the transfer surface 103 in a subsequent picking step.

FIG. 1d shows the receiving surface 104 in an initial configuration. The transfer surface 103 is provided with a plurality of micro elements 101 which are to be placed upon the receiving surface 104. In the shown embodiment, as can be seen in the detailed view, the receiving surface 104 is substantially flat.

During the rotation movement of the transfer surface 103, the micro elements 101 are placed upon the receiving surface 104 during the placing step shown in FIG. 1e. The transfer surface 103 and receiving surface 104 are configured such that all micro elements 101 can be transferred in a single step.

FIG. 1f shows a final configuration wherein all micro elements 101 are transferred to the receiving surface 104. The transfer surface 103 can be reused in a next transfer process.

In the shown preferred embodiment, the carrier 110 comprises at least one displaceable retaining structure 111 which is configured for carrying and/or retaining donor surfaces 102, which retaining structure 111 displaceable with respect to the carrier 100 in at least two directions. The retaining structure 111, and also the donor surfaces 102 provided thereon, extend in a plane that defines an x-direction and a y-direction, wherein the retaining structure 111 is configured to be altered in the x-direction and/or the y direction.

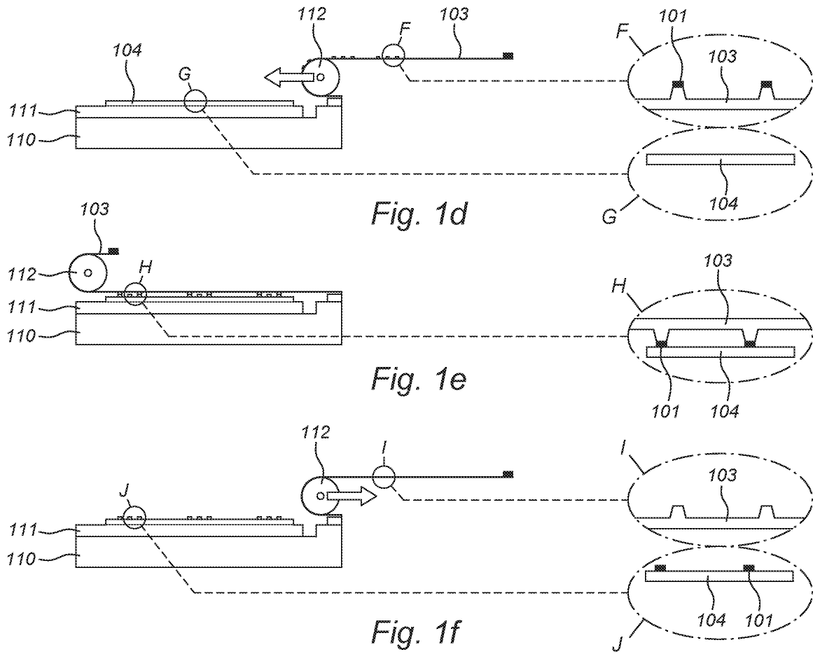

FIGS. 2a and 2b show a schematic representations of a picking step according to the present invention. FIG. 2a shows a side view similar to FIG. 1c. FIG. 2b shows a top view of FIG. 2a. In the transfer process there is made use of a system 200 according to the present invention. The system 200 is configured for transferring micro elements 201. The system 200 comprises a carrier 210 configured for carrying donor surfaces 202 and/or at least one receiving surface (not shown). The system 200 also comprises a transfer surface 203. The mutual orientation of at least part of the carrier 210 and the transfer surface 203 can be altered in at least two directions. In the shown embodiment, the transfer surface 203 is substantially flexible and the picking steps are performed by a rotational movement of the transfer surface 203 with respect to the donor surface(s). The flexible transfer surface 203 is rotatable around a roller 212. The carrier 210 comprises at least one displaceable retaining structure 211 which is configured for carrying and/or retaining donor surfaces 202, which retaining structure 211 displaceable with respect to the carrier 200 in at least two directions. The retaining structure 211, and also the donor surfaces 202 provided thereon, extend in a plane that defines an x-direction and a y-direction, wherein the retaining structure 211 is configured to be altered in the x-direction and/or the y direction. The figure shows that multiple micro elements 201 are transferred from the donor surface 202 to the transfer surface 203. FIG. 2b further shows optional configurations of the textured area of the transfer surface 203. The density of elevations 205 on the transfer surface can be relatively low having a large spacing between the elevations 205. It is also conceivable that the elevations 205 have a high density. Depending on the intended use, a combination of configurations may be applied too.

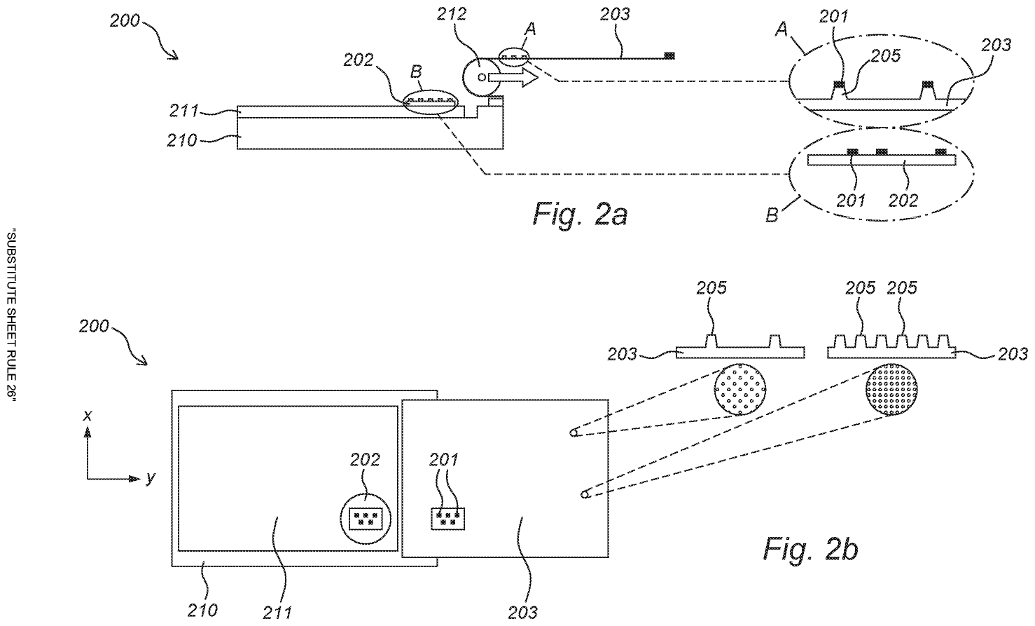

FIGS. 3a-3g show yet another schematic representation of a transfer process according to the present invention. FIGS. 3a-3g show subsequent process steps, wherein FIGS. 3a-3d shown the picking steps and FIGS. 3e-3f show the placing step. The picking steps and placing step are done via a rotational interaction as shown in the previous figures. The figures show a donor surface 302, a transfer surface 303 and a receiving surface 304. The donor surface 302 is provided upon a wafer. The mutual orientation of the donor surface 302 and the transfer surface 303 can be altered in at least two directions. This is in the shown embodiment achieved by altering the mutual orientation of the carrier 310 which carries the donor surface 302 and the transfer surface 303. The same altering can be applied for altering the mutual orientation of the transfer surface 303 and the receiving surface 304. It is shown in FIGS. 3a-3d that the position of the donor surface 302 upon the carrier 310 is altered between each picking step. In this way, all micro elements 301 of a single donor surface 302 can be picked up by the transfer surface 303 in an efficient manner. After step 3d, all micro elements 301 are transferred. The donor surface 302, and in particular the donor wafer, has been moved to the opposite corner of the carrier compared to the initial configuration and is void of micro elements 301. The transfer surface 303 has thus been “charged” with micro elements 301 in a step-by-step-repetition of picking steps. It can be seen that the density of micro elements 301 upon the transfer surface 302 is significantly lower the density thereof on the donor surface 302 in its initial state (FIG. 3a). After all micro elements 301 are transferred to the transfer elements 303, the receiving surface 304 can be put into position upon the carrier 310. The micro elements 301 are transferred in a single step, wherein all micro elements 301 are transferred from the transfer surface 303 to the receiving surface 304.

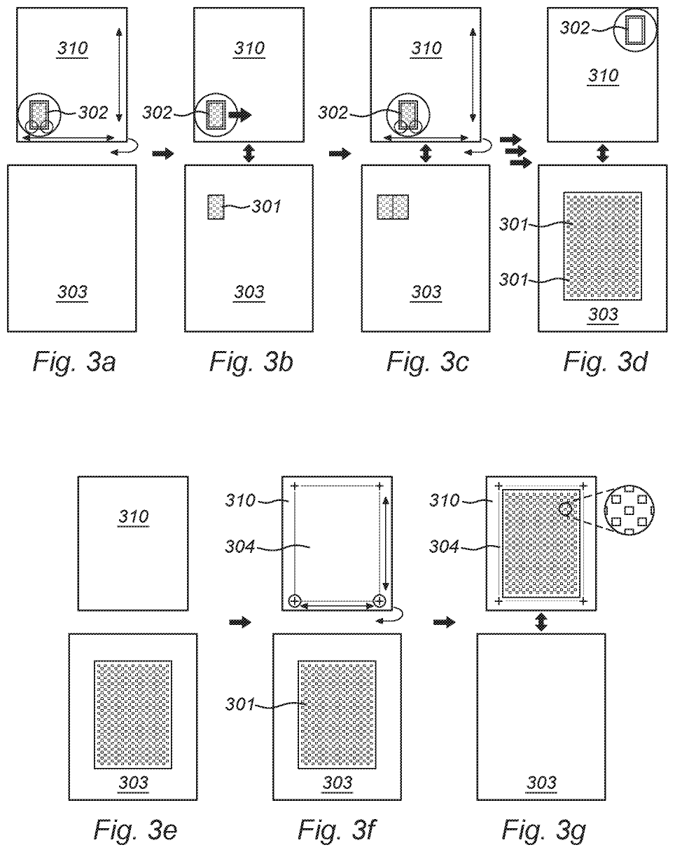

FIGS. 4a-4d show a further possible embodiment of a picking step according to the present invention. FIGS. 4a-4d show subsequent process steps of the picking process wherein multiple donor surfaces 402 are applied. The picking steps are done via a rotational interaction as shown in the previous figures. The figures show donor surfaces 402, a transfer surface 403 and a carrier 410 upon which the donor surfaces 402 are provided. The mutual orientation of the donor surfaces 402 and the transfer surface 303 is altered between each picking step such that after several picking steps, all micro elements 401 are transferred to the transfer surface 403. The placing step is not shown, but can be similar to the placing steps as shown in the previous figures.

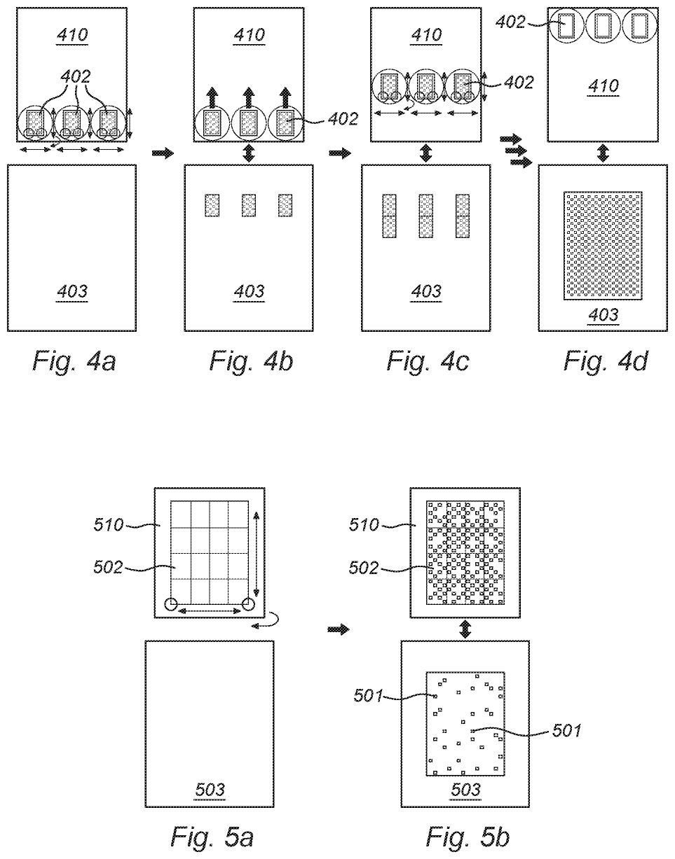

FIGS. 5a and 5b show an example of a further possible donor surface 502 having a substantially tiled configuration. The figures show donor surfaces 502, a transfer surface 503 and a carrier 510 upon which the donor surfaces 502 are provided. The figures show a single picking step, wherein some of the micro elements 501 are transferred from the donor surface 502 to the transfer surface 503. Multiple further picking steps and a transfer step could subsequently be performed.

It will be clear that the invention is not limited to the exemplary embodiments which are illustrated and described here, but that countless variants are possible within the framework of the attached claims, which will be obvious to the person skilled in the art. In this case, it is conceivable for different inventive concepts and/or technical measures of the above-described variant embodiments to be completely or partly combined without departing from the inventive idea described in the attached claims.

The verb ‘comprise’ and its conjugations as used in this patent document are understood to mean not only ‘comprise’, but to also include the expressions ‘contain’, ‘substantially contain’, ‘formed by’ and conjugations thereof.

1. A transfer process for micro elements, comprising:
at least one picking step wherein at least one micro element is picked up from at least one donor surface by at least one transfer surface; and
at least one placing step wherein at least one micro element is placed upon at least one receiving surface from at least one transfer surface;
wherein prior to a placing step at least two picking steps are performed and wherein the mutual orientation of at least one donor surface and at least one transfer surface is altered before each subsequent picking step.

2. The transfer process according to claim 1, wherein at least one transfer surface is substantially flexible.

3. The transfer process according to claim 1, wherein at least one picking step is performed by a rotational and/or rolling movement of at least one transfer surface with respect to at least one donor surface and/or wherein at least one placing step is performed by a rotational and/or rolling movement of at least one transfer surface with respect to at least one receiving surface.

4. The transfer process according to claim 1, wherein at least one picking step is a pressure initiated picking step and/or wherein at least one placing step is a pressure initiated placing step.

5. The transfer process according to claim 1, wherein at least one picking step is a thermally induced picking step and/or wherein at least one placing step is a thermally induced placing step.

6. The transfer process according to claim 1, wherein at least one donor surface extends in a plane that defines an x-direction and a y-direction, wherein the mutual orientation of at least one donor surface and at least one transfer surface is altered in the x-direction and/or the y direction before each subsequent picking step.

7. The transfer process according to claim 6, wherein at least one donor surface is altered in the x-direction and/or the y direction with respect to the transfer surface before each subsequent picking step and/or wherein at least one transfer surface is altered om the x-direction and/or the y direction with respect to the donor surface before each subsequent picking step.

8. (canceled)

9. The transfer process according to claim 1, wherein the mutual orientation of at least one donor surface and at least one transfer surface is altered by at least one predetermined distance before each subsequent picking step, wherein said predetermined distance is determined based upon at least one characteristic of at least one micro element.

10. The transfer process according to claim 1, wherein at least one transfer surface comprises a textured area.

11. The transfer process according to claim 1, wherein at least one transfer surface comprises at least one functional element.

12. (canceled)

13. The transfer process according to claim 1, wherein at least one picking step involves picking up a plurality of micro element from a plurality of donor surfaces.

14. The transfer process according to claim 1, wherein at least one picking step involves picking up a plurality of micro elements, wherein at least two micro element originate from different donor surfaces.

15. The transfer process according to claim 1, wherein at least one micro element comprises a micro light emitting diode and/or wherein at least one receiving surface is a display or display substrate.

16. The transfer process according to claim 1, wherein the area defined by at least one receiving surface is larger than the area defined by at least one donor surface.

17. (canceled)

18. The transfer process according to claim 1, comprising the step of adjusting the mutual orientation of at least one receiving surface and at least one transfer surface prior to a placing step.

19. A system for transferring micro elements, in particular via a transfer process according to claim 1, the system comprising:
at least one carrier configured for carrying at least one donor surface and/or at least one receiving surface; and
at least one transfer surface;
wherein the mutual orientation of at least part of the carrier and at least one transfer surface can be altered in at least two directions.

20. The system according to claim 19, wherein at least one carrier comprises at least one displaceable retaining structure which is configured for carrying and/or retaining at least one donor surface and/or at least one receiving surface, and wherein at least one retaining structure is displaceable with respect to the carrier in at least two directions.

21. The system according to claim 20, wherein at least one retaining structure extends in a plane that defines an x-direction and a y-direction, wherein at least one retaining structure is configured to be altered in the x-direction and/or the y direction.

22. The system according to claim 19, wherein at least carrier and at least one transfer surface are mutually displaceable via a rotational and/or rolling movement.

23. The system according to claim 19, comprising at least one housing wherein at least one carrier and/or at least one transfer surface are received within said housing.
